(19) United States
(12) Patent Application Publication
(10) Pub. No.: US 2006/0237709 A1
(43) Pub. Date: Oct. 26, 2006

(54) GaN-based compound semiconductor device

(75) Inventors: Sung-nam Lee, Suwon-si (KR); Ho-sun Paek, Suwon-si (KR); Joong-kon Son, Seoul (KR); Tan Sakong, Suwon-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/285,169

(22) Filed: Nov. 23, 2005

(30) Foreign Application Priority Data
Apr. 21, 2005 (KR) 10-2005-0033197

(51) Int. Cl. H01L 29/06; H01L 29/12

(52) U.S. Cl. 257/11

(57) ABSTRACT

A gallium nitride (GaN)-based compound semiconductor device having a structure improving a surface characteristic of a thin film growing on a substrate is provided. The GaN-based compound semiconductor device includes an AlₓIn_{y}Ga_{1-x-y}N substrate (0≦x≦1, 0≦y≦1, and 0≦x+y≦1) whose surface inclines toward a predetermined direction at an off-angle of greater than 0° and less than 1° with respect to the (0001) plane, and a GaN-based compound semiconductor layer grown on the surface of the substrate.

### CROSS-REFERENCE TO RELATED PATENT APPLICATION

This application claims the benefit of Korean Patent Application No. 10-2005-0033197, filed on Apr. 21, 2005, in the Korean Intellectual Property Office, the disclosure of which is incorporated herein in its entirety by reference.

### BACKGROUND OF THE DISCLOSURE

1. Field of the Disclosure

The present disclosure relates to a gallium nitride (GaN)-based compound semiconductor device, and more particularly, to a GaN-based compound semiconductor device having a structure improving a surface characteristic of a thin film growing on a substrate.

2. Description of the Related Art

In a conventional nitride-based semiconductor thin film grown on a heterogeneous substrate defects may be generated due to differences in lattice parameters, which degrade the characteristics of a device. Accordingly, it is essential to use a low-defect GaN substrate for growing a thin film of a nitride-based semiconductor device. However, the thin film growth on a GaN substrate has problems of irregular surface morphology, such as hillocks, crystallinity of a thin film, etc. In particular, generation of hillocks causes segregation of a certain component in a composition of a thin film growing on the hillock, so that the properties of a device are degraded, the manufacturing process for the thin film device becomes difficult, and thus yield is decreased.

Accordingly, when a thin film for a optoelectronic device is grown using a GaN substrate, technologies need to be developed for maintaining or improving a surface characteristic by improving surface morphology of the thin film growing in the substrate.

### SUMMARY OF THE DISCLOSURE

The present invention may provide a gallium nitride (GaN)-based compound semiconductor device having a structure for improving a surface characteristic of a thin film growing on a substrate.

According to an aspect of the present invention, there is provided a GaN-based compound semiconductor device including an AlₓIn_{y}Ga_{1-x-y}N substrate (0≦x≦1, 0≦y≦1, and 0≦x+y≦1) whose surface inclines toward a predetermined direction at an off-angle of greater than 0° and less than 1° to the (0001) plane, and a GaN-based compound semiconductor layer grown on the surface of the substrate. Here, the substrate can be doped with n-type or p-type impurities. The predetermined direction may be the <11-20> direction or the <1-100> direction, in which case the off-angle of the surface of the substrate may be greater than or equal to 0.01° and less than 1°.

According to another aspect of the present invention, there is provided a GaN-based compound semiconductor device including an AlₓIn_{y}Ga_{1-x-y}N substrate (0≦x≦1, 0≦y≦1, and 0≦x+y≦1) whose surface inclines toward a predetermined direction at an off-angle of greater than 0° and less than or equal to 1° with respect to a plane perpendicular to a non-polar direction, and a GaN-based compound semiconductor layer grown on the surface of the substrate. The plane perpendicular to the non-polar direction is one of the (11-20) plane, the (1-100) plane and the (1-102) plane. The substrate can be doped with n-type or p-type impurities. Preferably, the off-angle of the surface of the substrate is greater than or equal to 0.1° and less than or equal to 1°.

According to the present invention having the above-described construction, there is provided a GaN-based compound semiconductor device having excellent device characteristics by improving a surface characteristic of a thin film growing on a substrate.

### BRIEF DESCRIPTION OF THE DRAWINGS

The above and other features and advantages of the present invention are described in detail in exemplary embodiments thereof with reference to the attached drawings in which:

FIG. 1 is a schematic perspective view of a gallium nitride (GaN)-based compound semiconductor device according to a first embodiment of the present invention;

FIG. 2 is a detailed view of FIG. 1;

FIGS. 3A through 3C are optical interference microscope photographs showing the surface morphology of thin films growing at each surface off-angle on a substrate;

FIG. 4 is a schematic perspective view of a laser diode (LD) using a GaN-based compound semiconductor device according to a first embodiment of the present invention;

FIG. 5 is a schematic perspective view of a GaN-based compound semiconductor device according to a second embodiment of the present invention; and

FIG. 6 is a detailed view of FIG. 5.

### DETAILED DESCRIPTION OF EXEMPLARY EMBODIMENTS

Hereinafter, a gallium nitride (GaN)-based compound semiconductor device according to the present invention will now be described with reference to the accompanying drawings in which exemplary embodiments of the invention are shown. In the description, the thicknesses of layers and portions illustrated in the figures are exaggerated for clarity of the specification.

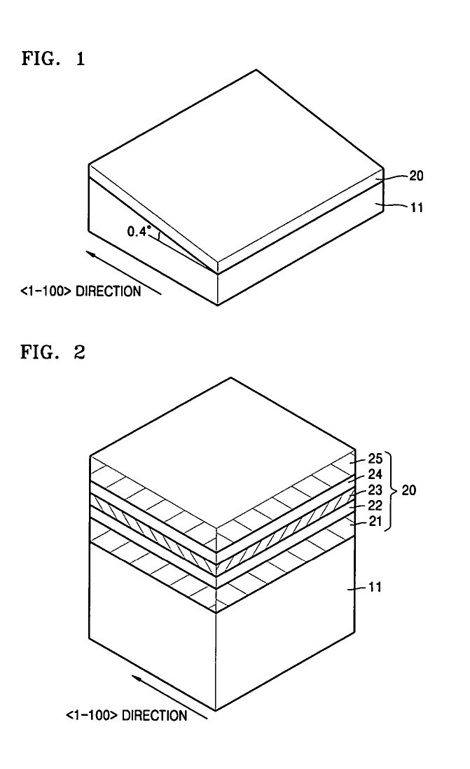

FIG. 1 is a schematic perspective view of a gallium nitride (GaN)-based compound semiconductor device according to a first embodiment of the present invention, and FIG. 2 is a detailed view of FIG. 1.

Referring to FIGS. 1 and 2, the GaN-based compound semiconductor device according to the first embodiment of the present invention includes an AlₓIn_{y}Ga_{1-x-y}N substrate 11 (0≦x≦1, 0≦y≦1, and 0≦x+y≦1) and a GaN-based compound semiconductor layer 20 grown on the surface of the substrate 11 by metal-organic chemical vapor deposition (MOCVD). The AlₓIn_{y}Ga_{1-x-y}N substrate 11 may be doped with n-type or p-type impurities. The surface of the substrate 11 inclines toward a predetermined direction at an off-angle of greater than 0° and less than 1° with respect to the (0001) plane. The predetermined direction may be the <11-20> direction or the <1-100> direction.

The GaN-based compound semiconductor layer 20 is a material layer made of AlₓIn_{y}Ga_{1-x-y}N (0≦x≦1, 0≦y≦1, and 0≦x+y≦1), formed as a monolayer or a multi-layer on the substrate 11 to construct a unit device. For example, the GaN-based compound semiconductor layer 20 may include an n-type cladding layer 21, an n-type light guide layer 22, a multiple quantum well active layer (MQW) 23, a p-type light guide layer 24 and a p-type cladding layer, 25, sequentially stacked on the substrate 11. The n-type cladding layer 21 and the p-type cladding layer 25 are formed of n-type aluminum-gallium-nitride (AlGaN) and p-type AlGaN, respectively. Also, the n-type light guide layer 22 and the p-type light guide layer 24 are formed of n-type GaN and p-type GaN, respectively. The MQW 23 includes a well layer formed of indium-gallium-nitride (InGaN) and a barrier layer formed of GaN or InGaN.

For the present invention having such constructions, the off-angle of the surface of the substrate 11 with respect to the (0001) plane is controlled to be in the range of 0° through 1°, to thereby obtain three different types of surface morphology for the GaN-based compound semiconductor layer 20 according to the off-angle. For example, by substituting “θ” for the off-angle, three different kinds of surface morphology, i.e. a hillock surface, a wavy surface and a mirror-like surface, are obtained in the range of 0≦θ≦0.1°, 0.1°≦θ≦0.4°, and 0.4°≦θ≦1.0°, respectively. Preferably, the off-angle is controlled to be in the range of 0.1° through 1.0°, to thereby obtain a GaN-based compound semiconductor layer without the hillock surface. More preferably, the off-angle is controlled to be in the range of 0.4° through 1.0°, to thereby obtain a mirror-like surface of the GaN-based compound semiconductor layer without having the hillock and wavy surface.

According to the present invention, when the GaN-based compound semiconductor layer 20 grows on the AlₓIn_{y}Ga_{1-x-y}N substrate 11, problems caused by generation of irregular surface morphology such as hillocks on the GaN-based compound semiconductor layer 20 can be reduced by controlling the off-angle of the substrate 11. In particular, the occurrence of indium segregations in an InGaN quantum well near the hillock can be reduced. Accordingly, by improving a surface characteristic of a thin film growing on the substrate 11, a GaN-based compound semiconductor device having excellent device characteristics can be obtained.

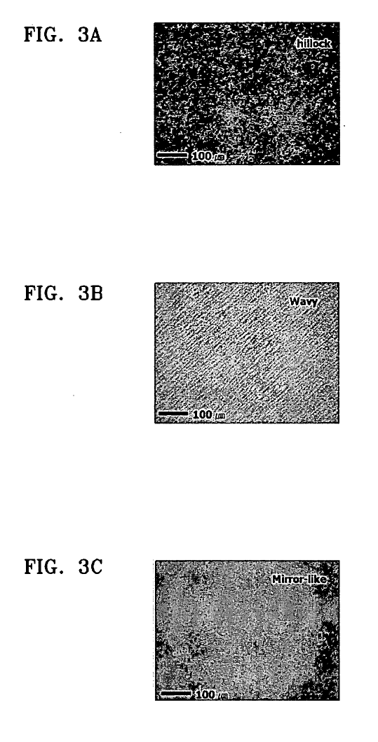

FIGS. 3A through 3C are optical interference microscope photographs showing the surface morphology of thin films growing on a substrate at each surface off-angle.

FIGS. 3A through 3C show surfaces of GaN-based compound semiconductor layers grown on nitride-based semiconductor substrates at off-angles of 0.019°, 0.35° and 0.42°, showing formations of a hillock surface, a wavy surface and a mirror-like surface, respectively.

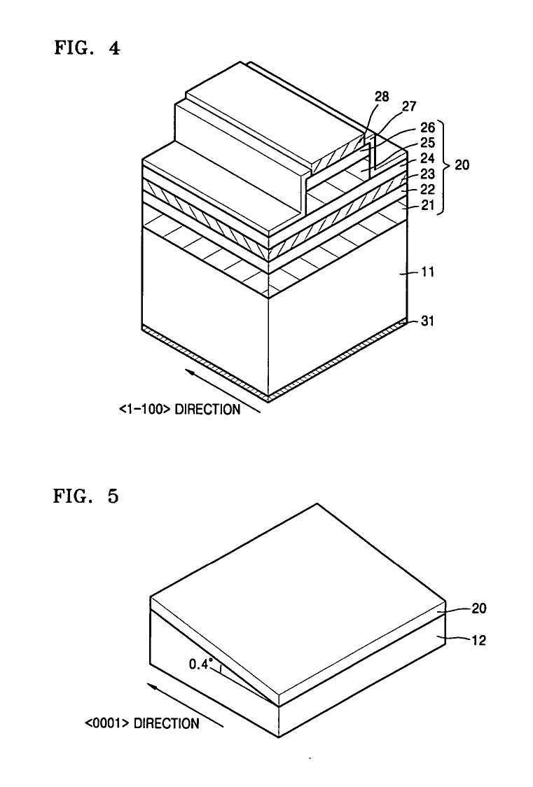

FIG. 4 is a schematic perspective view of a laser diode (LD) using a GaN-based compound semiconductor device according to the first embodiment of the present invention. Compared to the first embodiment in FIG. 2, a p-type contact layer 26 formed of p-type GaN is further stacked on the p-type cladding layer 25. In addition, the p-type cladding layer 25 and the p-type contact layer 26 are etched to a predetermined depth, and their side surfaces are covered with a protective insulative film 27. Moreover, a p-side electrode 28 and an n-side electrode 31 are prepared on the p-type contact layer 26 and the bottom surface of the AlₓIn_{y}Ga_{1-x-y}N substrate 11, respectively. The p-side electrode 28 and the n-side electrode 31 are nickel/gold (Ni/Au) and titanium/Aluminum (Ti/Al), respectively.

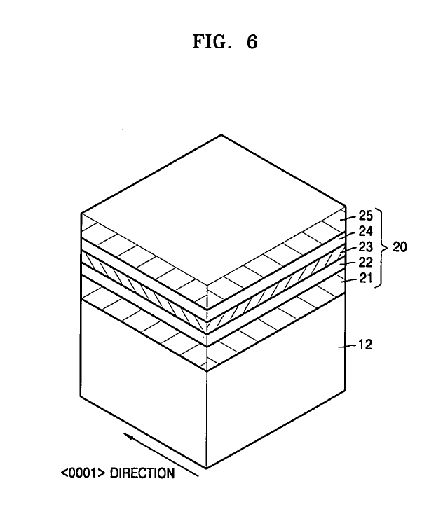

FIG. 5 is a schematic perspective view of a GaN-based compound semiconductor device according to a second embodiment of the present invention and FIG. 6 is a detailed view of FIG. 5. Here, explanations for the same components as in the first embodiment shown in FIGS. 1 and 2 will be omitted, and the same reference numerals will be used.

Referring to FIGS. 5 and 6, a GaN-based compound semiconductor device according to the second embodiment of the present invention includes an AlₓIn_{y}Ga_{1-x-y}N substrate 12 (0≦x≦1, 0≦y≦1, and 0≦x+y≦1) and a GaN-based compound semiconductor layer 20 grown on the substrate 12 by MOCVD. The AlₓIn_{y}Ga_{1-x-y}N substrate 12 may be doped with n-type or p-type impurities. The surface of the substrate 12 inclines toward a predetermined direction at an off-angle of greater than 0° and less than or equal to 10° with respect to any one of the planes perpendicular to a non-polar direction, such as the (11-20) plane, the (1-100) plane and the (1-102) plane. The off-angle of the surface of the substrate 12 may be greater than or equal to 0.1° and less than or equal to 1°. The predetermined direction includes all directions existing on any one of the planes perpendicular to the non-polar direction, such as the (11-20) plane, the (1-100) plane and the (1-102) plane. For example, when the substrate 12 has an off-angle with respect to the (1-100) plane, the predetermined direction may be a <0001> direction existing on the (1-100) plane.

For the present invention having such constructions, the off-angle of the substrate 12 with respect to any one of the planes perpendicular to the non-polar direction, such as the (11-20) plane, the (1-100) plane and the (1-102) plane, is controlled in the range of 0° through 10°, to thereby obtain three different kinds of surface morphology, i.e. the hillock surface, the wavy surface and the mirror-like surface of the GaN-based compound semiconductor layer 20 according to the off-angle, and the effects thereof are described above.

According to the present invention having the above-described construction, the problems caused by generation of irregular surface morphology such as hillocks on the GaN-based compound semiconductor layer growing on the substrate can be reduced. Accordingly, a GaN-based compound semiconductor device having excellent device characteristics can be obtained by improving a surface characteristic of a thin film growing on a substrate.

The GaN-based compound semiconductor device according to the present invention can be applied to optoelectronic devices such as a light emitting diode (LED), a laser diode (LD), and a photodetector, or other electronic devices.

While the present invention has been particularly shown and described with reference to exemplary embodiments thereof, it will be understood that the invention should, however, not be construed as being limited to the embodiments set forth herein; rather, it will be understood by those of ordinary skill in the art that various changes in form and details may be made therein without departing from the spirit and scope of the present invention as defined by the following claims.

What is claimed is:

1. A gallium nitride (GaN)-based compound semiconductor device comprising:
an AlₓIn_{y}Ga_{1-x-y}N substrate (0≦x≦1, 0≦y≦1, and 0≦x+y≦1) whose surface inclines toward a predetermined direction at an off-angle of greater than 0° and less than 1° with respect to the (0001) plane; and
a GaN-based compound semiconductor layer grown on the surface of the substrate.

2. The device of claim 1, wherein the substrate is doped as n-type or p-type.

3. The device of claim 1, wherein the predetermined direction is the <11-20> direction or the <1-100> direction.

4. The device of claim 3, wherein the off-angle of the surface of the substrate is greater than or equal to 0.01° and less than 1°.

5. A GaN-based compound semiconductor device comprising:
an AlₓIn_{y}Ga_{1-x-y}N substrate (0≦x≦1, 0≦y≦1, and 0≦x+y≦1) whose surface inclines toward a predetermined direction at an off-angle of greater than 0° and less than or equal to 10° with respect to a plane perpendicular to a non-polar direction; and
a GaN-based compound semiconductor layer grown on the surface of the substrate.

6. The device of claim 5, wherein the plane perpendicular to the non-polar direction is any one of the (11-20) plane, the (1-100) plane and the (1-102) plane.

7. The device of claim 5, wherein the substrate is doped with n-type or p-type impurities.

8. The device of claim 5, wherein the off-angle of the surface of the substrate is greater than or equal to 0.1° and less than or equal to 1°.

9. The device of claim 1, wherein the GaN-based compound semiconductor device is one of a light emitting diode (LED), a laser diode (LD), and a photodetector.

10. The device of claim 5, wherein the GaN-based compound semiconductor device is one of a light emitting diode (LED), a laser diode (LD), and a photodetector.
